(19) United States
(12) Patent Application Publication
(10) Pub. No.: US 2025/0007473 A1
(43) Pub. Date: Jan. 2, 2025

(54) SEMICONDUCTOR DEVICE

(71) Applicant: Murata Manufacturing Co., Ltd., Kyoto-fu (JP)

(72) Inventors: Takayuki TSUTSUI, Nagaokakyo-shi (JP); Shinnosuke TAKAHASHI, Nagaokakyo-shi (JP)

(73) Assignee: Murata Manufacturing Co., Ltd., Kyoto-fu (JP)

(21) Appl. No.: 18/883,118

(22) Filed: Sep. 12, 2024

Related U.S. Application Data
(63) Continuation of application No. PCT/JP2023/008089, filed on Mar. 3, 2023.

(30) Foreign Application Priority Data
Apr. 25, 2022 (JP) 2022-071655

(51) Int. Cl. H03F 3/24; H03F 1/56

(52) U.S. Cl. CPC H03F 3/245; H03F 1/56; H03F 2200/294; H03F 2200/441; H03F 2200/451

(57) ABSTRACT

A substrate ground conductor made of a semiconductor is provided. A transistor is configured with a collector layer, a base layer, and an emitter layer laminated on a substrate. A clamp circuit is configured with a plurality of elements disposed on the substrate. The clamp circuit is connected between the collector layer and the ground conductor or between the base layer and the ground conductor. The plurality of elements of the clamp circuit include a diode circuit made of a plurality of diodes, and a resistance element connected in series to the diode circuit. The resistance element is configured with a part of an epitaxial layer formed on the substrate.

### CROSS-REFERENCE TO RELATED APPLICATIONS

This application claims benefit of priority to International Patent Application No. PCT/JP2023/008089, filed Mar. 3, 2023, and to Japanese Patent Application No. 2022-071655, filed Apr. 25, 2022, the entire contents of each are incorporated herein by reference.

### BACKGROUND

### Technical Field

The present disclosure relates to a semiconductor device.

### Background Art

A radio-frequency power amplifier is one of main components mounted on a portable terminal. In order to increase the wireless transmission capacity of the portable terminal, a wireless communication standard that uses many frequency bands, such as carrier aggregation (CA), has been put into practical use. The circuit configuration of an RF front end has become complicated with an increase in the frequency bands used. Moreover, in order to make a frequency band of a sub 6 GHz band of a fifth generation mobile communication system (5G) usable, the circuit configuration of the RF front end is further complicated.

In a case where the circuit configuration of the RF front end is complicated, a loss due to a filter, a switch, or the like inserted into a transmission line from the radio-frequency power amplifier to an antenna increases. As a result, the radio-frequency power amplifier is required to have high output in addition to the correspondence to the plurality of frequency bands.

An output current and an output voltage of the radio-frequency power amplifier vary greatly in accordance with variations in load impedance. The radio-frequency power amplifier is required to have high output and is required to improve voltage-withstand characteristics in a case where the load impedance varies. By inserting a clamp diode between an output terminal (a collector of a bipolar transistor) of a power stage transistor of the radio-frequency power amplifier and the ground, the damage of the bipolar transistor during high-voltage output is suppressed.

In addition, a technique is known in which, in order to control an input impedance, an impedance element having a negative temperature coefficient and an impedance element having a positive temperature coefficient are inserted in series between a gate and a source of a field effect transistor as described, for example, in Japanese Unexamined Patent Application Publication No. 2006-41441. An anti-parallel diode is used as the impedance element having a negative temperature coefficient, and a polysilicon resistor or a diffusion resistor is used as the impedance element having a positive temperature coefficient. A resistance value of the anti-parallel diode at a small signal is in a range of gigaohms to petaohms. A resistance value of the polysilicon resistor or the diffusion resistor is also set in a range of gigaohms to petaohms.

### SUMMARY

The temperature characteristics of a rising voltage Vt of the clamp diode are negative. For this reason, at low temperatures, the rising voltage Vt increases and the output voltage is less likely to be clamped. On the contrary, at high temperatures, the rising voltage Vt decreases and the output voltage is likely to be clamped. A damage voltage of a transistor of a radio-frequency power amplifier circuit has a temperature dependence, and the damage voltage decreases particularly at low temperatures.

The clamp characteristics of the output voltage are adjusted by the number of stages of clamp diodes. In a case where the number of stages of the clamp diodes is set in accordance with low temperatures at which the damage voltage is relatively low, the output voltage is clamped even though there is a margin at high temperatures. Accordingly, the power or the efficiency at a load of 50Ω decreases. In a case where the number of stages of the clamp diodes is set in accordance with high temperatures at which the damage voltage is relatively high, the clamping cannot be sufficiently performed at low temperatures, and the transistor is likely to be damaged.

As described in Japanese Unexamined Patent Application Publication No. 2006-41441, in a case where the impedance element having a positive temperature coefficient and the impedance element having a negative temperature coefficient are connected in series, it is possible to compensate for the temperature characteristic. However, as described in Japanese Unexamined Patent Application Publication No. 2006-41441, a circuit in which a resistor in a range of gigaohms to petaohms is inserted in series does not function as the clamp circuit for preventing damage in the radio-frequency power amplifier because the resistance value is too large.

Accordingly, the present disclosure provides a semiconductor device that can suppress a damage at low temperatures and suppress a decrease in power and efficiency at high temperatures in a semiconductor device used for a radio-frequency amplifier circuit.

According to one aspect of the present disclosure, there is provided a semiconductor device including a substrate made of a semiconductor; a ground conductor provided on the substrate; a transistor including a collector layer, a base layer, and an emitter layer that are laminated on the substrate; and at least one clamp circuit that is configured with a plurality of elements disposed on the substrate and that is connected between the collector layer and the ground conductor or between the base layer and the ground conductor. The plurality of elements of the clamp circuit include a diode circuit made of plurality of diodes, and a resistance element connected in series to the diode circuit. The resistance element is configured with a part of an epitaxial layer formed on the substrate.

Temperature characteristics of a rising voltage of a diode and temperature characteristics of a resistance value of the resistance element configured with a part of the epitaxial layer show mutually opposite tendencies. As the resistance value of the resistance element increases at high temperatures, a decrease in the impedance of the clamp circuit during clamping is suppressed. Accordingly, a decrease in power or efficiency at high temperatures is suppressed. As the resistance value of the resistance element decreases at low temperatures, sufficient clamp characteristics are maintained at low temperatures, and the damage of the transistor is suppressed.

### BRIEF DESCRIPTION OF THE DRAWINGS

FIGS. 1A and 1B are a block diagram of a semiconductor device according to a first embodiment and an equivalent circuit diagram of a part of the semiconductor device;

FIG. 2 is a schematic sectional view of a portion in which a transistor, a diode, and a resistance element of the semiconductor device according to the first embodiment are disposed;

FIG. 3 is a diagram showing the planar disposition of a plurality of the transistors, a plurality of the diodes, and two resistance elements of the semiconductor device according to the first embodiment;

FIG. 4 is a graph showing the measurement results of current-voltage characteristics of the diode (FIG. 2);

FIG. 5 is a graph showing the measurement results of the temperature dependence of a resistance value of the resistance element (FIG. 2) configured with an epitaxial layer;

FIGS. 6A and 6B are graphs showing the calculation results of a relationship between an output power Pout and a consumption current Ice in a case where a clamp circuit is connected to an output terminal of an amplifier circuit, and FIGS. 6C and 6D are graphs showing the calculation results of a relationship between the output power Pout and a power gain;

FIG. 7 is a graph showing the calculation results of a relationship between the output power Pout and efficiency in a case where the clamp circuit is connected to the output terminal of the amplifier circuit;

FIG. 8 is a schematic sectional view of a portion in which a transistor, a diode, and a resistance element of a semiconductor device according to a second embodiment are disposed;

FIG. 9 is a graph showing the results obtained by measuring the temperature dependence of a resistance value of a conductive region made of n-type GaAs;

FIGS. 10A and 10B are a block diagram of a semiconductor device according to a third embodiment and an equivalent circuit diagram of a part of the semiconductor device;

FIG. 11 is a schematic sectional view of a portion in which a transistor, a diode, and a resistance element of a semiconductor device according to the third embodiment are disposed;

FIG. 12 is a graph showing the measurement results of current-voltage characteristics of a diode having a Schottky barrier;

FIG. 13 is a graph showing a calculation result of a relationship between input power and attenuation to a driver stage amplifier circuit of the semiconductor device according to the third embodiment;

FIGS. 14A and 14B are a block diagram of a semiconductor device according to a fourth embodiment and an equivalent circuit diagram of a part of the semiconductor device;

FIG. 15 is a block diagram of a semiconductor device according to a modification example of the fourth embodiment;

FIG. 16 is a schematic sectional view of a portion in which a transistor, a diode, and a resistance element of a semiconductor device according to a fifth embodiment are disposed;

FIG. 17 is a diagram showing the planar disposition of a plurality of the transistors, a plurality of the diodes, and two resistance elements of the semiconductor device according to the fifth embodiment;

FIG. 18 is a block diagram of a radio-frequency module according to a sixth embodiment;

FIG. 19 is a plan view showing an example of the disposition of various circuit components mounted on a module substrate; and

FIG. 20 is a schematic sectional view of a part of a semiconductor device according to a seventh embodiment.

### DETAILED DESCRIPTION

### First Embodiment

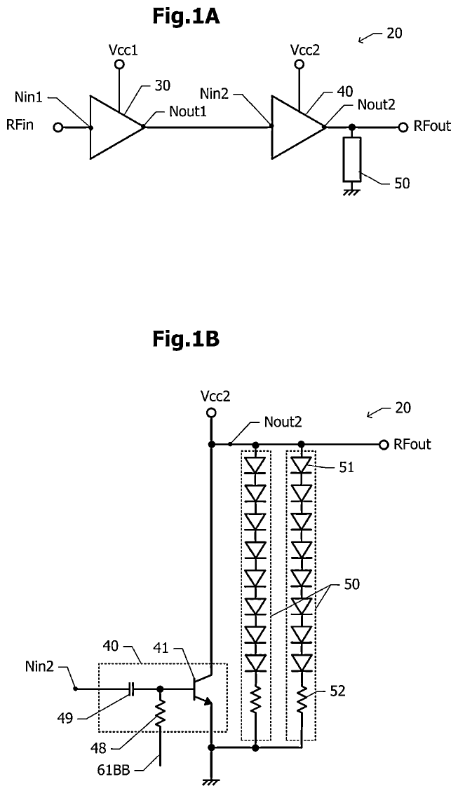

A semiconductor device according to a first embodiment will be described with reference to FIGS. 1A to 7. FIG. 1A is a block diagram of a semiconductor device 20 according to the first embodiment. The semiconductor device 20 according to the first embodiment includes a driver stage amplifier circuit 30 and a power stage amplifier circuit 40. A radio-frequency input signal input from an input terminal RFin is input to an input node Nin1 of the driver stage amplifier circuit 30. A radio-frequency signal output from an output node Nout1 of the driver stage amplifier circuit 30 is input to an input node Nin2 of the power stage amplifier circuit 40. A radio-frequency signal output from an output node Nout2 of the power stage amplifier circuit 40 is output from an output terminal RFout to an external circuit.

An output-side clamp circuit 50 is connected between the output node Nout2 of the power stage amplifier circuit 40 and a ground potential. A power supply voltage is applied to the driver stage amplifier circuit 30 and the power stage amplifier circuit 40 from respective power terminals Vcc1 and Vcc2. An impedance matching circuit is inserted as necessary on the input side of the driver stage amplifier circuit 30, between the driver stage amplifier circuit 30 and the power stage amplifier circuit 40, and on the output side of the power stage amplifier circuit 40.

FIG. 1B is an equivalent circuit diagram of a part of the semiconductor device 20 according to the first embodiment. The power stage amplifier circuit 40 has a configuration in which a plurality of cells, each of which is made of a transistor 41, a base ballast resistance element 48, and an input capacitor 49 are connected in parallel. FIG. 1B shows only one cell. The radio-frequency signal input from the input node Nin2 is input to a base of the transistor 41 via the input capacitor 49. A bias is supplied from a base bias wiring 61BB to the base of the transistor 41 via the base ballast resistance element 48. A power supply voltage is applied to a collector of the transistor 41 from the power terminal Vcc2. The collector of the transistor 41 functions as the output node Nout2 of the power stage amplifier circuit 40.

Two output-side clamp circuits 50 are connected in parallel to each other between the collector (output node Nout2) of the transistor 41 and the ground potential. One output-side clamp circuit 50 may be provided. Each of the output-side clamp circuits 50 includes a diode circuit made of a plurality of diodes 51 connected in multiple stages, and a resistance element 52 connected in series to the diode circuit.

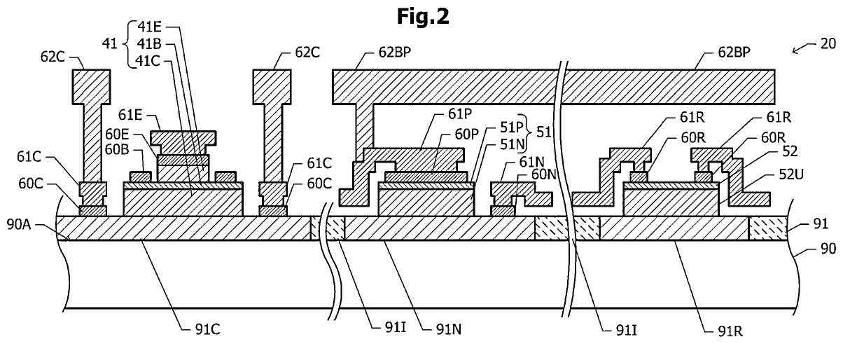

FIG. 2 is a schematic sectional view of a portion of the semiconductor device 20 according to the first embodiment, in which the transistor 41, the diode 51, and the resistance element 52 are disposed. For example, an epitaxial layer 91 is formed on a first surface 90A, which is one surface of a substrate 90 made of a single crystal compound semiconductor such as semi-insulating GaAs, by epitaxially growing a compound semiconductor. An n-type dopant is doped during the growth of the epitaxial layer 91. After the epitaxial layer 91 is formed, an insulated region (referred to as an element separation region 911) is formed by performing ion implantation of hydrogen, helium, or the like in a partial region of the epitaxial layer 91. The region that is not insulated has n-type conductivity. For example, the epitaxial layer 91 includes an n-type sub-collector region 91C, conductive regions 91N and 91R, and the like.

The transistor 41 is formed on the sub-collector region 91C. The transistor 41 includes a mesa-shaped portion including a collector layer 41C and a base layer 41B laminated thereon, and an emitter layer 41E disposed on a partial region of the base layer 41B. A heterojunction bipolar transistor (HBT) is configured by the collector layer 41C, the base layer 41B, and the emitter layer 41E. As an example, the collector layer 41C is formed of n-type GaAs, the base layer 41B is formed of p-type GaAs, and the emitter layer 41E is formed of n-type InGaP. A ledge structure may be adopted in which the emitter layer 41E is disposed in the entire region of the upper surface of the base layer 41B, and the contact layer or the like is disposed on a partial region of the emitter layer 41E.

A collector electrode 60C is disposed in a partial region of the upper surface of the sub-collector region 91C, in which the collector layer 41C is not disposed. The collector electrode 60C is electrically connected to the collector layer 41C via the sub-collector region 91C. The base electrode 60B is disposed in a partial region of the upper surface of the base layer 41B, in which the emitter layer 41E is not disposed. The base electrode 60B is electrically connected to the base layer 41B. An emitter electrode 60E is disposed on the emitter layer 41E. The emitter electrode 60E is electrically connected to the emitter layer 41E.

The diode 51 is disposed on a partial region of the conductive region 91N. The diode 51 includes a cathode layer 51N and an anode layer 51P disposed thereon. As an example, the cathode layer 51N is formed of n-type GaAs, and the anode layer 51P is formed of p-type GaAs. A pn junction diode is configured by the cathode layer 51N and the anode layer 51P.

A cathode electrode 60N is disposed in a partial region of the upper surface of the conductive region 91N, in which the cathode layer 51N is not disposed. The cathode electrode 60N is electrically connected to the cathode layer 51N via the conductive region 91N. An anode electrode 60P is disposed on the anode layer 51P. The anode electrode 60P is electrically connected to the anode layer 51P.

An underlying layer 52U made of, for example, n-type GaAs is disposed on a partial region of the conductive region 91R, and a resistance element 52 made of, for example, p-type GaAs is disposed thereon. Two resistance element electrodes 60R are disposed on the upper surface of the resistance element 52 with a space therebetween. The resistance element electrodes 60R are each electrically connected to the resistance element 52.

The collector layer 41C, the cathode layer 51N, and the underlying layer 52U are formed by patterning the same epitaxial layer epitaxially grown on the epitaxial layer 91. That is, the collector layer 41C, the cathode layer 51N, and the underlying layer 52U are configured of different portions of the same epitaxial layer. In a plurality of semiconductor layers configured with different portions of the same epitaxial layer, constituent elements, types of dopants, doping concentrations, and directions of crystal axes are the same.

The base layer 41B, the anode layer 51P, and the resistance element 52 are also configured with different portions of the same epitaxial layer. The collector layer 41C, the base layer 41B, and the emitter layer 41E constitute a mesa disposed on the epitaxial layer 91. The diode 51 including the cathode layer 51N and the anode layer 51P also constitutes a mesa disposed on the epitaxial layer 91. The underlying layer 52U and the resistance element 52 also constitute a mesa disposed on the epitaxial layer 91. That is, the resistance element 52 is configured with a part of the mesa disposed on the epitaxial layer 91.

In FIG. 2, although the side surface of each mesa is shown to be substantially perpendicular to the first surface 90A, the side surface of the mesa may be an inclined surface depending on etching conditions in patterning the epitaxial layer or the crystal plane orientation of the epitaxial layer.

A first wiring layer is disposed on the transistor 41, the diode 51, the resistance element 52, and the like. In FIG. 2, the description of an interlayer insulating film between wiring layers is omitted. The first wiring layer includes a collector wiring 61C, an emitter wiring 61E, an anode wiring 61P, a cathode wiring 61N, a resistance element wiring 61R, and the like.

The collector wiring 61C and the emitter wiring 61E are respectively connected to the collector electrode 60C and the emitter electrode 60E through a contact hole provided in each interlayer insulating film. The anode wiring 61P and the cathode wiring 61N are respectively connected to the anode electrode 60P and the cathode electrode 60N through a contact hole provided in each interlayer insulating film. The two resistance element wirings 61R are connected to the two respective resistance element electrodes 60R through a contact hole provided in each interlayer insulating film.

A second wiring layer is disposed on the first wiring layer. The second wiring layer includes a collector wiring 62C, a pad 62BP, and the like. In FIG. 2, the description of an interlayer insulating film between the first wiring layer and the second wiring layer is omitted. The second-layer collector wiring 62C is connected to the first-layer collector wiring 61C through a contact hole provided in an interlayer insulating film below the second-layer collector wiring 62C. The pad 62BP is connected to the anode wiring 61P connected to one diode 51 (the diode 51 at the position farthest from the resistance element 52 in terms of the circuit) through a contact hole provided in an interlayer insulating film below the pad 62BP. The pad 62BP extends to a region overlapping the resistance element 52.

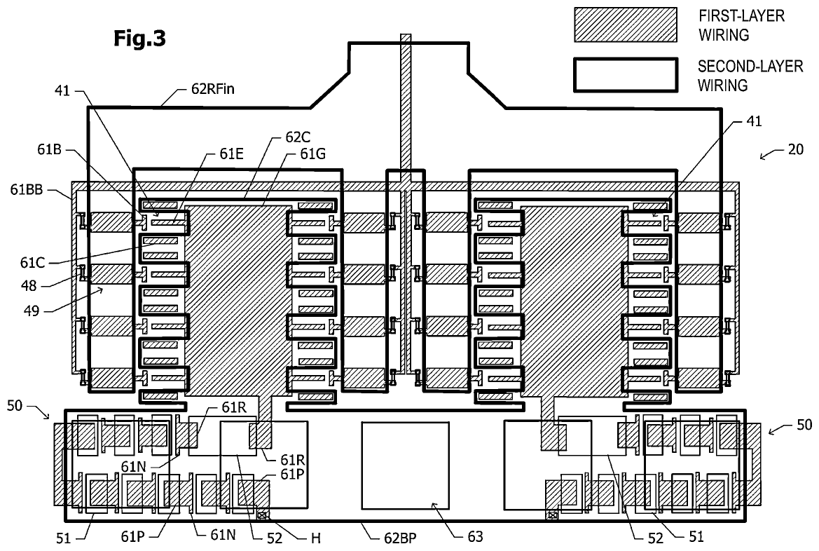

FIG. 3 is a diagram showing the planar disposition of a plurality of the transistors 41, a plurality of the diodes 51, and two resistance elements 52 of the semiconductor device 20 according to the first embodiment. In FIG. 3, the wiring included in the first wiring layer is hatched, and the wiring included in the second wiring layer is represented by relatively thick contour lines.

In this configuration, 16 transistors 41 are disposed in a matrix form of 4 rows and 4 columns. In FIG. 3, eight transistors 41 located in a first column and a second column from the left constitute one cell block, and eight transistors 41 located in a third column and a fourth column constitute another cell block. The planar disposition of a plurality of components included in each of the two cell blocks has a mirror symmetry relationship. Hereinafter, the configuration of a cell block including the eight transistors 41 in the first column and the second column will be described. A column of four transistors 41 arranged in the column direction is referred to as a transistor column.

The first-layer emitter wiring 61E, the first-layer collector wiring 61C, and a first-layer base wiring 61B are connected to each of the transistors 41. As shown in FIG. 2, the emitter wiring 61E and the collector wiring 61C are electrically connected to the emitter layer 41E and the collector layer 41C of the transistor 41. The base wiring 61B is connected to the base electrode 60B (FIG. 2).

A ground conductor 61G is disposed between a first transistor column and a second transistor column. The ground conductor 61G is disposed in the first wiring layer, which is the same as the emitter wiring 61E or the like. The emitter wiring 61E connected to each of the eight transistors 41 in the first column and the second column is connected to the ground conductor 61G. A back surface electrode (not shown) is formed on a back surface of the substrate 90. The back surface electrode is connected to the ground conductor 61G via a via hole penetrating the substrate 90.

The second-layer collector wiring 62C is disposed in a region overlapping with each of a plurality of the first-layer collector wirings 61C and in a region between the transistors in the first transistor column and the second transistor column. The second-layer collector wiring 62C is connected to the plurality of first-layer collector wirings 61C through the contact hole provided in the interlayer insulating film below the second-layer collector wiring 62C. The plurality of first-layer collector wirings 61C are connected to each other via the second-layer collector wiring 62C.

A plurality of the first-layer base wirings 61B are each connected to the base electrode 60B (FIG. 2) through a contact hole provided in an interlayer insulating film below the first-layer base wiring 61B. Each of the base wirings 61B extends in a direction away from the ground conductor 61G with a spot connected to the base electrode 60B as a starting point.

A signal input wiring 62RFin is disposed along each of the first and second transistor columns. The signal input wiring 62RFin is disposed in the second wiring layer. Each of the base wirings 61B intersects the signal input wiring 62RFin. The input capacitor 49 having the base wiring 61B and the signal input wiring 62RFin as electrodes is formed at an intersection spot of both the wirings. Each of the tips of the plurality of base wirings 61B is connected to a common base bias wiring 61BB via the base ballast resistance element 48. The base bias wiring 61BB is disposed in the first wiring layer.

The signal input wirings 62RFin disposed along each of the four columns of the plurality of transistors 41 are connected to each other. Similarly, the base bias wirings 61BB disposed along each of the four columns of the plurality of transistors 41 are also connected to each other.

A pad 62BP extending in a row direction is disposed to be adjacent to the two cell blocks. The pad 62BP is disposed in the second wiring layer and is connected to two second-layer collector wirings 62C. The collector wirings 62C disposed in each cell block are connected to each other via the pad 62BP. The pad 62BP is covered with a protective film (not shown), and a part of the upper surface of the pad 62BP is exposed in a plurality of openings 63 provided in the protective film. A bonding wire is bonded to the exposed region.

The output-side clamp circuit 50 (FIGS. 1A and 1B) is disposed for each cell block. The plurality of diodes 51 and the resistance element 52, which constitute each of the output-side clamp circuits 50, are disposed at positions overlapping the pad 62BP in a plan view. One resistance element wiring 61R connected to the resistance element 52 is connected to the ground conductor 61G. The other resistance element wiring 61R is connected to the cathode wiring 61N of one diode 51.

The plurality of diodes 51 are disposed side by side in the row direction and are folded back in the middle. The anode wiring 61P connected to one diode 51 is continuous with the cathode wiring 61N connected to the adjacent diode 51. The anode wiring 61P connected to the diode 51 that is the farthest from the resistance element 52 in terms of the circuit is connected to the pad 62BP through a contact hole H provided in an interlayer insulating film. In the semiconductor device 20 according to the first embodiment, a pad-on element (POE) structure in which the pad 62BP and the plurality of diodes 51 and the resistance element 52 constituting the output-side clamp circuit 50 overlap each other is adopted.

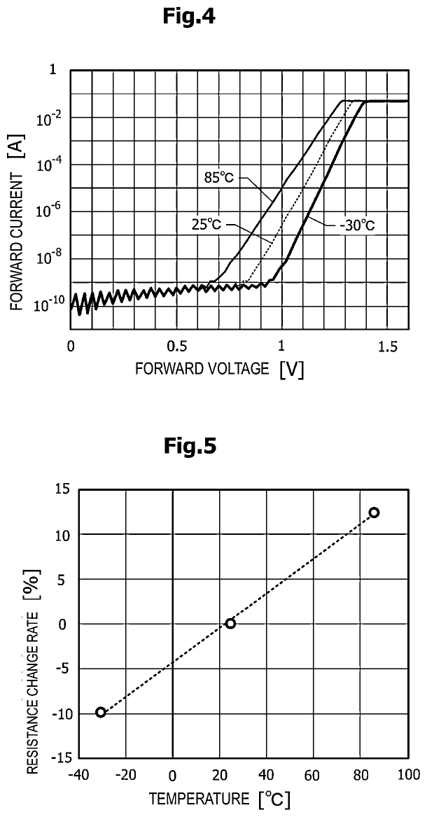

Next, the excellent effects of the first embodiment will be described with reference to FIGS. 4 to 7.

FIG. 4 is a graph showing the measurement results of current-voltage characteristics of the diode 51 (FIG. 2). The horizontal axis represents the forward voltage in the unit of [V], and the vertical axis represents the forward current in the unit of [A]. A thick solid line, a broken line, and a thin solid line in the graph of FIG. 4 show current-voltage characteristics at respective temperatures of −30° C., 25° C., and 85° C. It can be seen that the rising voltage of the current increases as the temperature decreases. That is, a decrease in the temperature acts in a direction in which the output voltage of the power stage amplifier circuit 40 (FIG. 1A and FIG. 1B) is less likely to be clamped.

FIG. 5 is a graph showing the measurement results of the temperature dependence of a resistance value of the resistance element 52 (FIG. 2) configured with a part of the epitaxial layer made of p-type GaAs. The horizontal axis represents the temperature in the unit of [° C.], and the vertical axis represents the resistance change rate based on the resistance value at a temperature of 25° C. in the unit of [%]. It can be seen that the resistance value increases as the temperature rises. It can be seen that the resistance value increases by approximately 2% in a case where the temperature rises by 10° C. in a temperature range of −30° C. to 85° C. For this reason, the rise in temperature acts in the direction of increasing the impedance of the output-side clamp circuit 50 (FIG. 1A and FIG. 1B).

In a case where the number of stages of the diodes 51 of the output-side clamp circuit 50 is set with priority given to low temperatures at which the damage of the transistor 41 is likely to occur, the output voltage is likely to be clamped even though there is a margin in the output because the rising voltage of the diodes 51 decreases at high temperatures. In the first embodiment, since the resistance value of the resistance element 52 is relatively high at high temperatures, the impedance of the output-side clamp circuit 50 in a clamped state is high at high temperatures. For this reason, it is possible to suppress a decrease in the output due to the clamping of the output voltage.

In addition, since the resistance value of the resistance element 52 is relatively low at low temperatures, even in a case where the resistance element 52 is inserted in series into a diode circuit in which a plurality of diodes 51 are connected in multiple stages, an increase in the impedance of the output-side clamp circuit 50 during clamping is suppressed. For this reason, a sufficient effect of suppressing the damage of the transistor 41 can be maintained.

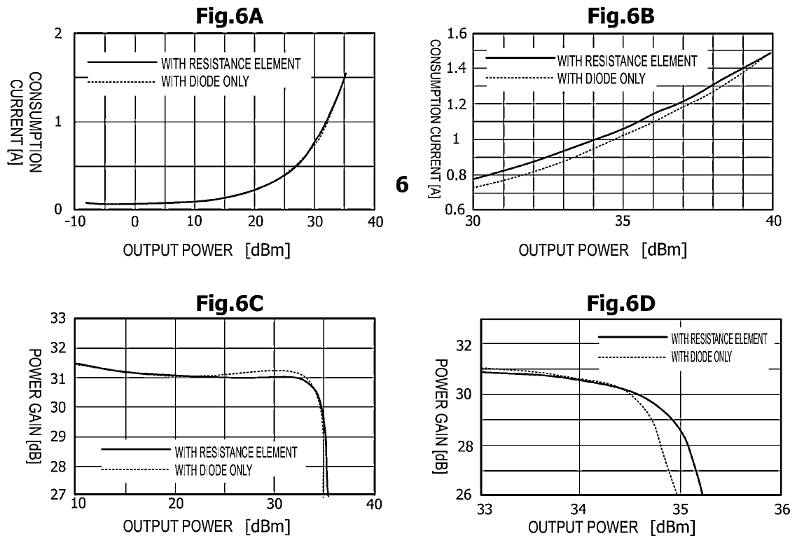

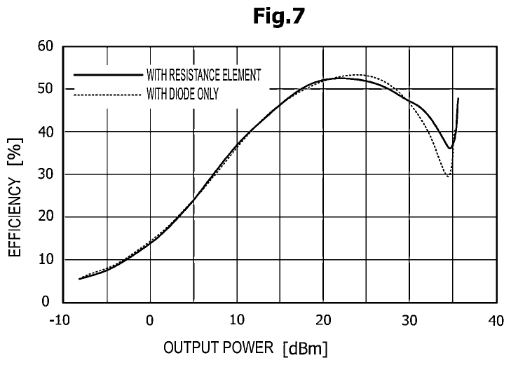

FIGS. 6A and 6B are graphs showing the calculation results of a relationship between output power and consumption current in a case where an output-side clamp circuit is connected to an output node of an amplifier circuit, and FIGS. 6C and 6D are graphs showing the calculation results of a relationship between the output power and a power gain. FIG. 6B is an enlarged graph of a part of FIG. 6A, and FIG. 6D is an enlarged graph of a part of FIG. 6C. FIG. 7 is a graph showing the calculation results of a relationship between the output power and efficiency calculated from the consumption current in a case where the clamp circuit is connected to the output node of the amplifier circuit. Here, the “consumption current” means an average value of the currents supplied from the power terminals Vcc1 and Vcc2 during radio-frequency operation in the two-stage amplifier circuit shown in FIG. 1A.

The horizontal axis of the graphs from FIG. 6A to FIG. 7 represents the output power in the unit of [dBm]. The vertical axis of FIG. 6A and FIG. 6B represents the consumption current in the unit of [A]. The vertical axis of FIG. 6C and FIG. 6D represents the power gain in the unit of [dB]. The vertical axis of FIG. 7 represents the efficiency in the unit of [%].

The power supply voltage was set to 5.5 V, and a load impedance was set to 50Ω. The solid line in each graph shows the calculation results of an amplifier circuit in which an output-side clamp circuit (hereinafter, referred to as “clamp circuit with resistance element”) is configured with a six-stage diode circuit and a resistance element, and the broken line shows the calculation results of an amplifier circuit in which a clamp circuit (hereinafter, referred to as “clamp circuit with diode only”) is configured with an eight-stage diode circuit. The resistance value of the resistance element is set to a value at which the impedance of the output-side clamp circuit can be kept low such that a sufficient clamp effect can be obtained at low temperatures. This value can be calculated from the relationship between the number of stages of diodes and the value of the voltage applied to collectors. An instantaneous peak voltage applied to the collectors during the radio-frequency operation may be several times the power supply voltage. In the calculation of the graphs from FIG. 6A to FIG. 6D, conditions such as the resistance value of the resistance element, the characteristics of the diodes, and the number of stages of the diodes are set such that the device can withstand the instantaneous peak voltage generated.

As shown in FIGS. 6A and 6B, the consumption current is substantially equal between the amplifier circuit having the clamp circuit with the resistance element and the amplifier circuit having the clamp circuit with only the diode. As shown in FIGS. 6C and 6D, it can be seen that, in the amplifier circuit having the clamp circuit with the resistance element, the output power characteristics are improved compared to the amplifier circuit having only the clamp circuit with the diode. As shown in FIG. 7, it can be seen that, in a case where the amplifier circuit having the clamp circuit with the resistance element is compared with the amplifier circuit having the clamp circuit with only the diode, the efficiency of the amplifier circuit having the clamp circuit with the resistance element is improved in a range in which the output power is 30 dBm or more and 35 dBm or less (i.e., from 30 dBm to 35 dBm).

As shown in the graphs from FIG. 6A to FIG. 7, by inserting the resistance element 52 (FIG. 1B) into the output-side clamp circuit 50, the output can be increased and the efficiency can be improved under the condition in which the consumption current is substantially equal.

In a region where the pad 62BP (FIG. 3) is disposed in a plan view, a dummy mesa is usually disposed in order to increase the flatness of an underlying surface of the pad 62BP. Here, the dummy mesa means a mesa that is configured with a part of another epitaxial layer laminated on the epitaxial layer 91 (FIG. 2) and that does not participate in the function of an electronic circuit disposed on the substrate 90. In the first embodiment, the dummy mesa is disposed instead of the mesa including the resistance element 52 (FIG. 3). For this reason, it is not necessary to newly secure a region in which the resistance element 52 is to be disposed.

Next, a preferred value of the resistance value of the resistance element 52 (FIG. 1B) will be described. It is preferable that the resistance value of the resistance element 52 is set to 1/10 or more of the load impedance in order to suppress a significant decrease in the impedance of the output-side clamp circuit 50 in a case where the diode 51 is turned on and the output voltage is clamped even though there is a margin in the output power at high temperatures. In a case where the load impedance is 50Ω, it is preferable that the resistance value of the resistance element 52 is set to 5Ω or more.

It is preferable that the resistance value of the resistance element 52 is set to ½ or less of the load impedance in order to prevent the damage of the transistor 41 in a case where the output voltage is clamped at low temperatures. In a case where the load impedance is 50Ω, it is preferable that the resistance value of the resistance element 52 is 25Ω or less. For example, in a case where the resistance value of the resistance element configured with Si or the like is set in a range from gigaohms to petaohms, as in the circuit described in Japanese Unexamined Patent Application Publication No. 2006-41441, a sufficient effect of preventing the damage of the transistor 41 is not obtained because the resistance value is too large in a radio-frequency amplifier circuit of a portable terminal configured with a heterojunction bipolar transistor.

Next, a modification example of the first embodiment will be described.

In the first embodiment, as shown in FIG. 1B, the resistance element 52 is connected to a ground side of the diode circuit made of the plurality of diodes 51. As another configuration, the resistance element 52 may be connected to the diode circuit on the output node Nout2 side, or the resistance element 52 may be inserted in the middle of the plurality of diodes 51 connected in multiple stages.

### Second Embodiment

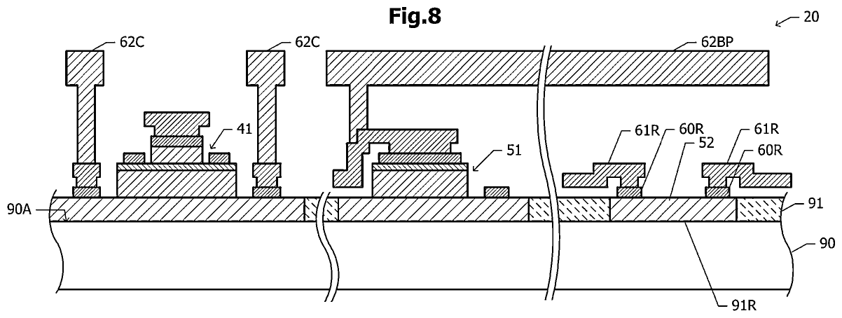

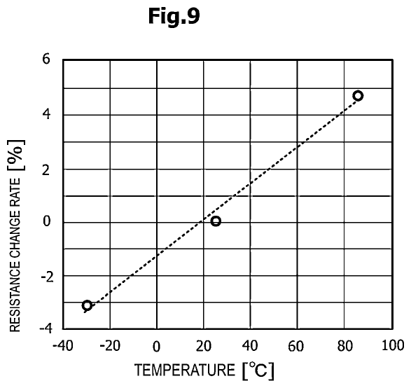

Next, a semiconductor device according to a second embodiment will be described with reference to FIGS. 8 and 9. The description of the configurations in common with the semiconductor device 20 according to the first embodiment described with reference to FIGS. 1A to 7 will be omitted below.

FIG. 8 is a schematic sectional view of a portion of the semiconductor device 20 according to the second embodiment, in which the transistor 41, the diode 51, and the resistance element 52 are disposed. The configurations of the transistor 41 and the diode 51 are the same as the configurations of the transistor 41 and the diode 51 of the semiconductor device 20 (FIG. 2) according to the first embodiment.

In the first embodiment (FIG. 2), the resistance element 52 is configured with a part of the epitaxial layer that is the same as the base layer 41B of the transistor 41. In contrast, in the second embodiment, the resistance element 52 is configured by the conductive region 91R which is a part of the epitaxial layer 91 that is epitaxially grown on the first surface 90A of the substrate 90. The resistance element 52 is configured with, for example, a part of an n-type GaAs epitaxial layer. The two resistance element electrodes 60R are connected to the conductive region 91R.

FIG. 9 is a graph showing the results obtained by measuring the temperature dependence of a resistance value of the conductive region 91R made of n-type GaAs. The horizontal axis represents the temperature in the unit of [° C.], and the vertical axis represents the resistance change rate based on the resistance value at a temperature of 25° C. in the unit of [%]. Similar to the measurement results shown in FIG. 5, it can be seen that the resistance value increases as the temperature rises. It can be seen that, in a case where the temperature rises by 10° C. in a temperature range of −30° C. to 85° C., the resistance value increases by approximately 0.7%. For this reason, the rise in temperature acts in the direction of increasing the impedance of the output-side clamp circuit 50 (FIG. 1A and FIG. 1B).

Next, the excellent effects of the second embodiment will be described. The temperature characteristics of the resistance element 52 used in the output-side clamp circuit 50 (FIG. 1A and FIG. 1B) of the semiconductor device 20 according to the second embodiment show the same tendency as the temperature characteristics of the resistance element 52 used in the output-side clamp circuit 50 (FIG. 1A and FIG. 1B) of the semiconductor device 20 according to the first embodiment. For this reason, similar to the first embodiment, also in the second embodiment, a decrease in the output due to the clamping of the output voltage at high temperatures can be suppressed, and a sufficient effect of suppressing the damage of the transistor 41 at low temperatures can be maintained.

### Third Embodiment

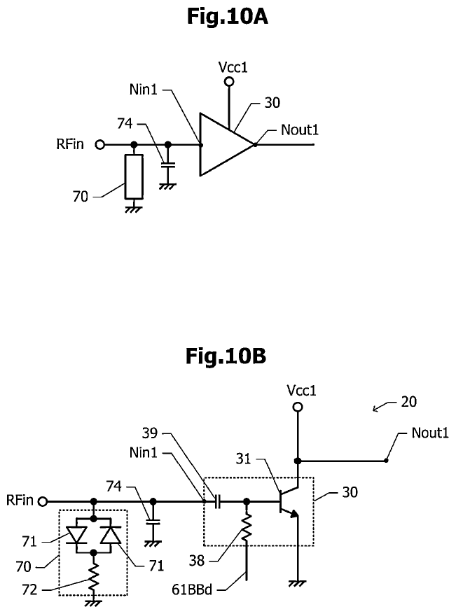

Next, a semiconductor device according to a third embodiment will be described with reference to FIGS. 10A to 13. The description of the configurations in common with the semiconductor device 20 according to the first embodiment described with reference to FIGS. 1A to 7 will be omitted below.

FIG. 10A is a block diagram of the semiconductor device 20 according to the third embodiment. In the first embodiment, the output-side clamp circuit 50 is connected to the output node Nout2 of the power stage amplifier circuit 40, and the clamp circuit is not connected to the input node Nin1 of the driver stage amplifier circuit 30. In contrast, in the third embodiment, an input-side clamp circuit 70 is connected between the input node Nin1 of the driver stage amplifier circuit 30 and the ground potential. Moreover, a capacitor 74 is connected between the input node Nin1 and the ground potential. The capacitor 74 functions as the impedance matching circuit.

FIG. 10B is an equivalent circuit diagram of a part of the semiconductor device 20 according to the third embodiment. The driver stage amplifier circuit 30 has a configuration in which a plurality of cells each made of a transistor 31, a base ballast resistance element 38, and an input capacitor 39 are connected in parallel. FIG. 10B shows only one cell. A radio-frequency signal input to the input terminal RFin is input to a base of the transistor 31 via the input capacitor 39. A bias is supplied from a base bias wiring 61BBd to the base of the transistor 31 via the base ballast resistance element 38.

A power supply voltage is applied to a collector of the transistor 31 from the power terminal Vcc1. An amplified radio-frequency signal is output from the output node Nout1, that is, the collector of the transistor 31. The input-side clamp circuit 70 includes a diode circuit made of two diodes 71 connected in anti-parallel, and a resistance element 72 connected in series to the diode circuit.

The input-side clamp circuit 70 has a function of suppressing the voltage amplitude of the radio-frequency signal input to the driver stage amplifier circuit 30. By suppressing the voltage amplitude of the radio-frequency signal input to the driver stage amplifier circuit 30, the damage of a transistor of the power stage amplifier circuit connected to a posterior stage of the driver stage amplifier circuit 30 is suppressed in a case where an excessive radio-frequency signal is input.

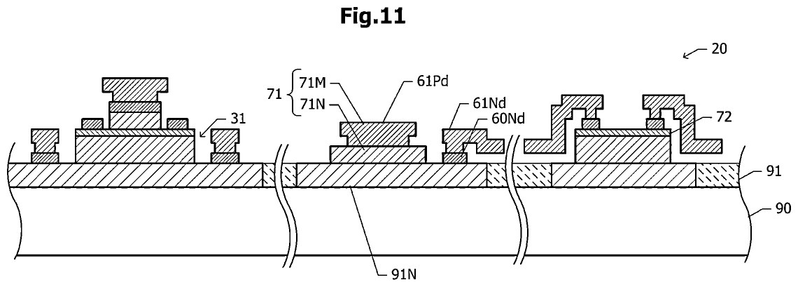

FIG. 11 is a schematic sectional view of a portion of the semiconductor device 20 according to the third embodiment, in which the transistor 31, the diodes 71, and the resistance element 72 are disposed. The basic configurations of the transistor 31 and the resistance element 72 are the same as the configurations of the transistor 41 and the resistance element 52 of the semiconductor device 20 (FIG. 2) according to the first embodiment. The number of transistors 31 of the driver stage amplifier circuit 30 is smaller than the number of transistors 41 of the power stage amplifier circuit 40. In addition, the dimensions of each of the transistors 31 in a plan view are not necessarily the same as the dimensions of each of the transistors 41 of the power stage amplifier circuit 40. In addition, the resistance value of the resistance element 72 is optimized for the input-side clamp circuit 70 and is not necessarily the same as the resistance value of the resistance element 52 of the semiconductor device 20 (FIG. 2) according to the first embodiment. The resistance value of the resistance element 72 can be adjusted by adjusting the width and the length of the resistance element 72 in a plan view.

In the semiconductor device 20 (FIG. 2) according to the first embodiment, a pn junction diode is used as the diode 51 but in the semiconductor device 20 according to the third embodiment, a Schottky barrier diode is used as each diode 71. The diode 71 includes a cathode layer 71N made of an n-type compound semiconductor, for example, n-type GaAs, which is disposed on the conductive region 91N of the epitaxial layer 91, and a barrier metal layer 71M that forms a Schottky contact with an upper surface of the cathode layer 71N.

A cathode electrode 60Nd is disposed in a region of the upper surface of the conductive region 91N, in which the cathode layer 71N is not disposed. The cathode electrode 60Nd is electrically connected to the cathode layer 71N via the conductive region 91N. An anode wiring 61Pd and a cathode wiring 61Nd included in the first wiring layer are respectively connected to a barrier metal layer 71M and the cathode electrode 60Nd.

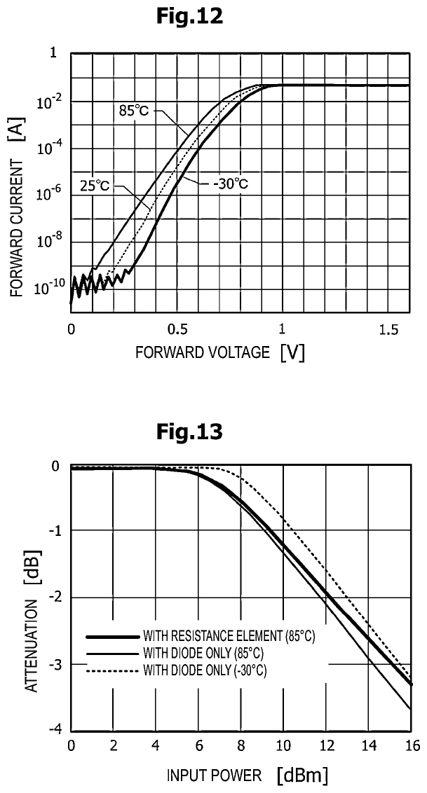

FIG. 12 is a graph showing the measurement results of current-voltage characteristics of the diode 71 having a Schottky barrier. The horizontal axis represents the forward voltage in the unit of [V], and the vertical axis represents the forward current in the unit of [A]. A thick solid line, a broken line, and a thin solid line in the graph of FIG. 12 show measurement results at respective temperatures of −30° C., 25° C., and 85° C. It can be seen that the rising voltage of the diode 71 decreases as the temperature rises. Comparing FIG. 4 with FIG. 12, it can be seen that the rising voltage of the diode 71 having the Schottky barrier is lower than the rising voltage of the diode 51 (FIG. 2) having the pn junction.

FIG. 13 is a graph showing the calculation results of a relationship between the input power and an attenuation of the radio-frequency signal input to the driver stage amplifier circuit 30. The horizontal axis represents the input power in the unit of [dBm], and the vertical axis represents the attenuation by the input-side clamp circuit 70 in the unit of [dB]. In the graph shown in FIG. 13, a thick solid line indicates the attenuation of an input-side clamp circuit configured with only two diodes connected in anti-parallel, and a thin solid line and a broken line indicate the attenuation of the input-side clamp circuit 70 including a diode circuit connected in anti-parallel and the resistance element 72. In addition, the thick solid line and the thin solid line indicate the attenuation at a temperature of 85° C., and the broken line indicates the attenuation at a temperature of −30° C.

It is preferable that the resistance value of the resistance element 72 is set to 1/10 or more of the input impedance in a case where the driver stage amplifier circuit 30 is viewed from the input-side clamp circuit 70 such that an attenuation in a case where the voltage amplitude of the radio-frequency signal input from the input terminal RFin is clamped is not too large at high temperatures. For example, the input impedance is 50Ω. In this case, the resistance value of the resistance element 72 is preferably 5Ω or more. In addition, in order to obtain a sufficient clamp function at low temperatures, it is preferable that the resistance value of the resistance element 72 is set to be equal to or less than the value of the input impedance in a case where the driver stage amplifier circuit 30 is viewed from the input-side clamp circuit 70. For example, the input impedance is 50Ω. In this case, the resistance value of the resistance element 72 is preferably 50Ω or less. The calculation for deriving the graph shown in FIG. 13 is performed under the condition that the requirement is satisfied.

In a case where the input power increases, the diode 71 is turned on to clamp the input voltage. For this reason, the attenuation increases as the input power increases. In a case where the input-side clamp circuit 70 is configured with only diodes, the rising voltage of the diode 71 decreases as the temperature rises. Therefore, the input power at which the attenuation starts is smaller and the attenuation is larger at a temperature of 85° C. than at a temperature of −30° C. Even though the damage voltage of the transistor 41 of the power stage amplifier circuit 40 at high temperatures is higher than the damage voltage at low temperatures, the attenuation of the input power increases.

In a case where the resistance element 72 is inserted into the input-side clamp circuit 70, the impedance of the input-side clamp circuit 70 increases compared to a case where the input-side clamp circuit 70 is configured only with the diode 71 even in a state in which the voltage amplitude of the input signal is clamped. For this reason, as compared to a temperature of 85° C., the input-side clamp circuit 70 in which the resistance element 72 is inserted has a smaller attenuation compared to a case where the input-side clamp circuit 70 is configured with only the diode 71. For example, the input power at which 3 dB suppression occurs increases from approximately 14 dBm to approximately 15 dBm and approaches the input power at which 3 dB suppression occurs at −30° C.

Next, the excellent effects of the third embodiment will be described.

In the third embodiment, as shown in FIG. 13, it is possible to suppress the unnecessary attenuation of the input power to the driver stage amplifier circuit 30 at high temperatures. In addition, in a case where the input power increases excessively at low temperatures, the amplitude of the input voltage can be suppressed, and the damage of the transistor 41 of the power stage amplifier circuit 40 of the posterior stage can be suppressed.

As shown in FIG. 5, since the resistance value of the resistance element 72 decreases at low temperatures, the deterioration of the clamp characteristics due to the insertion of the resistance element 72 are suppressed.

The power of the input signal of the driver stage amplifier circuit 30 (FIG. 10A) is in a range of, for example, 6 dBm or more and 10 dBm or less (i.e., from 6 dBm to 10 dBm). In order to clamp the voltage amplitude of the input signal, it is preferable that the rising voltage of the diode is approximately 0.3 V or less. The rising voltage of the pn junction diode using GaAs is approximately 0.8 V at normal temperature as shown in FIG. 4. Therefore, in a case where the pn junction diode is used for the input-side clamp circuit 70, sufficient clamp characteristics cannot be obtained. In the third embodiment, since a Schottky barrier diode having a rising voltage of 0.3 V or less is used as the diode 71 of the input-side clamp circuit 70, sufficient clamp characteristics can be realized.

### Fourth Embodiment

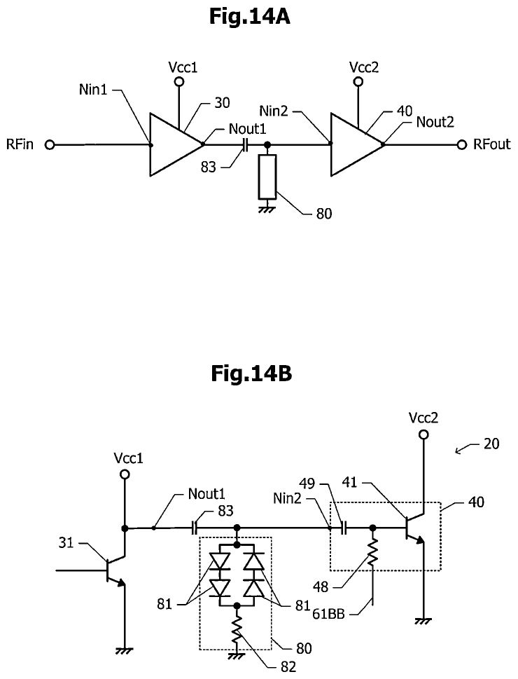

Next, a semiconductor device according to a fourth embodiment will be described with reference to FIGS. 14A and 14B. The description of the configurations in common with the semiconductor device 20 according to the first embodiment described with reference to FIGS. 1A to 7 will be omitted below.

FIG. 14A is a block diagram of the semiconductor device 20 according to the fourth embodiment. The semiconductor device 20 (FIG. 1A) according to the first embodiment includes the output-side clamp circuit 50 connected between the output node Nout2 of the power stage amplifier circuit 40 and the ground potential. In contrast, the semiconductor device 20 according to the fourth embodiment does not include the output-side clamp circuit 50, and includes an inter-stage clamp circuit 80 connected between the input node Nin2 of the power stage amplifier circuit 40 and the ground potential.

A capacitor 83 is inserted in series between the inter-stage clamp circuit 80 and the output node Nout1 of the driver stage amplifier circuit 30. The capacitor 83 has a function of cutting a direct-current voltage applied to the inter-stage clamp circuit 80.

FIG. 14B is an equivalent circuit diagram of a part of the semiconductor device 20 according to the fourth embodiment. The inter-stage clamp circuit 80 includes a diode circuit made of a plurality of diodes 81 connected in anti-parallel and a resistance element 82 connected in series to the diode circuit, similar to the input-side clamp circuit 70 (FIG. 10B). In the input-side clamp circuit 70, one diode 51 and the other one diode 51 are connected in anti-parallel but in the inter-stage clamp circuit 80, each of two diode circuits connected in anti-parallel includes two diodes 81 connected in two stages. For this reason, the voltage (hereinafter, referred to as clamp voltage) at both ends of the inter-stage clamp circuit 80 in a case where each diode 81 is turned on is higher than the clamp voltage of the input-side clamp circuit 70.

The resistance element 82 is configured with a part of an epitaxial layer formed on the first surface 90A of the substrate 90, similar to the resistance element 72 of the input-side clamp circuit 70 and the resistance element 52 of the output-side clamp circuit 50. The inter-stage clamp circuit 80 suppresses the voltage amplitude of the radio-frequency signal input to the power stage amplifier circuit 40.

Next, the excellent effects of the fourth embodiment will be described. The inter-stage clamp circuit 80 can suppress the damage of the transistor 41 due to the input of the radio-frequency signal with an excessive voltage amplitude to the power stage amplifier circuit 40, in order to suppress the voltage amplitude of the radio-frequency signal to be input to the power stage amplifier circuit 40.

Moreover, since the resistance element 82 is inserted into the inter-stage clamp circuit 80, it is possible to suppress the unnecessary attenuation at high temperatures, similar to the attenuation characteristics of the input-side clamp circuit 70 shown in FIG. 13. On the contrary, at low temperatures at which the damage of the transistor 41 is likely to occur, the radio-frequency signal input to the power stage amplifier circuit 40 can be sufficiently attenuated.

The number of stages of the diodes 81 used in the inter-stage clamp circuit 80 may be set according to the voltage value of a targeted clamp voltage. In a case where it is desired to increase the clamp voltage, the number of stages of the diodes 81 may be increased. In addition, the Schottky barrier diode and the pn junction diode may be mixed depending on the targeted clamp voltage.

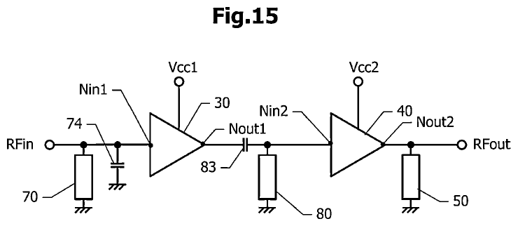

Next, a semiconductor device according to a modification example of the fourth embodiment will be described with reference to FIG. 15.

FIG. 15 is a block diagram of the semiconductor device according to the modification example of the fourth embodiment. In the fourth embodiment (FIG. 14A), the clamp circuit is not connected to the input node Nin1 of the driver stage amplifier circuit 30 and the output node Nout2 of the power stage amplifier circuit 40. In the modification example shown in FIG. 15, the input-side clamp circuit 70 is connected between the input node Nin1 of the driver stage amplifier circuit 30 and the ground potential, and the output-side clamp circuit 50 is connected between the output node Nout2 of the power stage amplifier circuit 40 and the ground potential. Moreover, the capacitor 74 is connected between the input node Nin1 of the driver stage amplifier circuit and the ground potential.

The configuration of the input-side clamp circuit 70 is the same as the configuration of the input-side clamp circuit 70 (FIG. 10B) of the semiconductor device according to the third embodiment. The configuration of the output-side clamp circuit 50 is the same as the configuration of the output-side clamp circuit 50 (FIG. 1B) of the semiconductor device according to the first embodiment.

By connecting the input-side clamp circuit 70, the inter-stage clamp circuit 80, and the output-side clamp circuit 50, the effect of suppressing the damage of a transistor can be enhanced. Any one of the input-side clamp circuit 70, the inter-stage clamp circuit 80, or the output-side clamp circuit 50 may be omitted, and only two clamp circuits may be connected.

### Fifth Embodiment

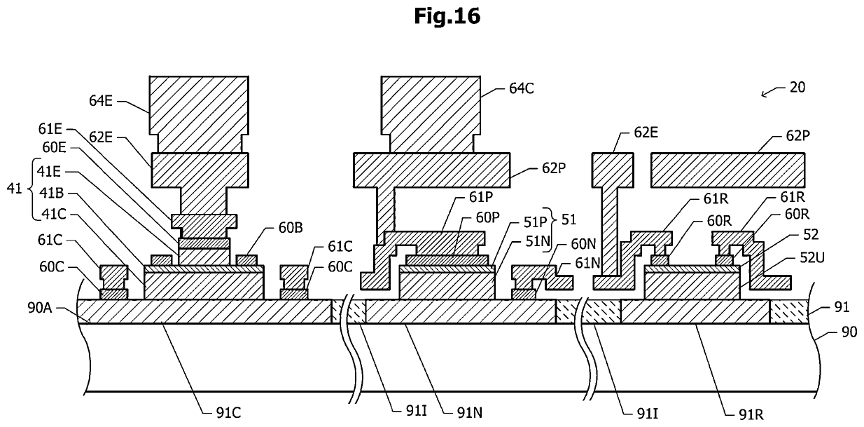

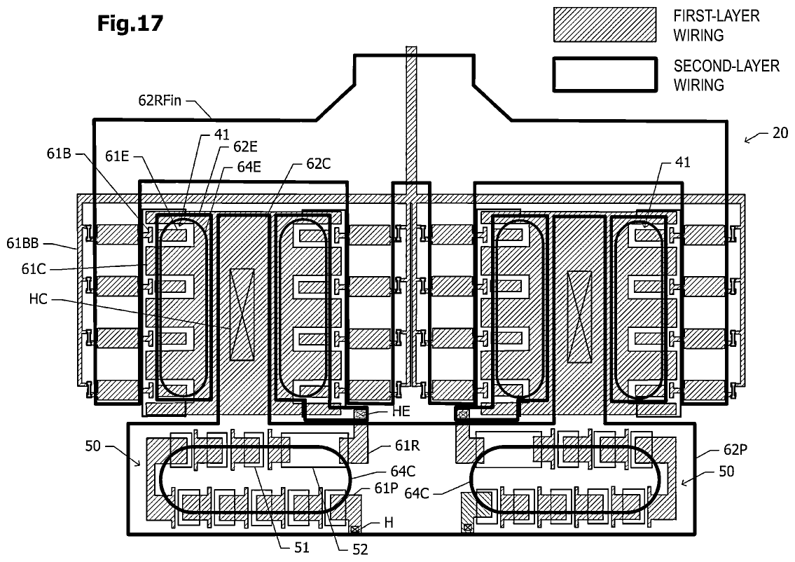

Next, a semiconductor device according to a fifth embodiment will be described with reference to FIGS. 16 and 17. The description of the configurations in common with the semiconductor device 20 according to the first embodiment described with reference to FIGS. 1A to 7 will be omitted below. The block diagram and the equivalent circuit diagram of the semiconductor device 20 according to the fifth embodiment are the same as the block diagram (FIG. 1A) and the equivalent circuit diagram (FIG. 1B) of the semiconductor device 20 according to the first embodiment. Although the semiconductor device 20 (FIG. 2) according to the first embodiment is face-up mounted on a module substrate or the like with the first surface 90A (element forming surface) of the substrate 90 facing away from the module substrate or the like, the semiconductor device 20 according to the fifth embodiment is face-down mounted on the module substrate or the like with the first surface 90A (element forming surface) of the substrate 90 facing the module substrate or the like.

FIG. 16 is a schematic sectional view of a portion of the semiconductor device 20 according to the fifth embodiment, in which the transistor 41, the diode 51, and the resistance element 52 are disposed. In the first embodiment (FIG. 2), a second-layer emitter wiring is not disposed on the first-layer emitter wiring 61E connected to the transistor 41. In contrast, in the fifth embodiment, the second-layer emitter wiring 62E is disposed on the first-layer emitter wiring 61E, and a conductor protrusion 64E for ground is disposed on the second-layer emitter wiring 62E.

In the first embodiment (FIG. 3), the first-layer resistance element wiring 61R is connected to the ground conductor 61G and the diode 51 in the first wiring layer. In contrast, in the fifth embodiment, one resistance element wiring 61R is connected to the second-layer emitter wiring 62E.

In addition, in the first embodiment (FIGS. 2 and 3), the anode electrode 60P of the diode 51, which is farthest from the resistance element 52 in terms of the circuit, is connected to the pad 62BP for bonding via the first-layer anode wiring 61P. In contrast, in the fifth embodiment, the anode electrode 60P of the diode 51, which is farthest from the resistance element 52 in terms of the circuit, is connected to the pad 62P serving as a base of a conductor protrusion 64C via the first-layer anode wiring 61P. The conductor protrusion 64C is disposed on the pad 62P.

As the conductor protrusions 64C and 64E, for example, a Cu pillar bump, an Au bump, a solder ball bump, or the like is used. The conductor protrusions 64C and 64E are used as an external connection terminal connected to a circuit of a module substrate or the like.

FIG. 17 is a diagram showing the planar disposition of a plurality of the transistors 41, a plurality of the diodes 51, and two resistance elements 52 of the semiconductor device 20 according to the fifth embodiment. In FIG. 17, the wiring included in the first wiring layer is hatched, and the wiring included in the second wiring layer is represented by relatively thick contour lines.

In the first embodiment (FIG. 3), each of the ground conductors 61G is disposed between the first transistor column and the second transistor column or between a third transistor column and a fourth transistor column. In contrast, in the fifth embodiment, the collector wirings 61C connected to the respective collector electrodes 60C (FIG. 2) of the transistors 41 extend to a region between the first transistor column and the second transistor column and a region between the third transistor column and the fourth transistor column.

Each of the second-layer collector wirings 62C is disposed between the first transistor column and the second transistor column or between the third transistor column and the fourth transistor column. The second-layer collector wiring 62C is connected to the first-layer collector wiring 61C through a contact hole HC provided in an interlayer insulating film below the second-layer collector wiring 62C.

In the fifth embodiment, the pad 62P serving as the base of the conductor protrusion 64C such as a bump is disposed on the second wiring layer in a region where the pad 62BP for bonding of the semiconductor device 20 (FIG. 3) according to the first embodiment is disposed. The pad 62P is connected to the second-layer collector wiring 62C.

The first-layer emitter wiring 61E is connected to each of the plurality of transistors 41. In the first embodiment (FIG. 3), the first-layer emitter wiring 61E is connected to the ground conductor 61G but in the fifth embodiment, the first-layer emitter wiring 61E is isolated in the first wiring layer. Each of the second-layer emitter wirings 62E is disposed at a position overlapping each of the first-layer first to fourth transistor columns in a plan view. The second-layer emitter wiring 62E is connected to the first-layer emitter wiring 61E through a contact hole provided in an interlayer insulating film below the second-layer emitter wiring 62E. The second-layer emitter wiring 62E functions as a ground conductor.

The second-layer emitter wiring 62E, which overlaps the second and third transistor columns, is connected to the resistance element wiring 61R through a contact hole HE provided in the interlayer insulating film below the second-layer emitter wiring 62E. The disposition of the two resistance elements 52 and the plurality of diodes 51 is the same as the disposition of the resistance elements 52 and the plurality of diodes 51 of the semiconductor device 20 (FIG. 3) according to the first embodiment. The two resistance elements 52 and the plurality of diodes 51 are disposed at positions overlapping the pad 62P in a plan view.

The anode wiring 61P connected to the diode 51 that is farthest from the resistance element 52 in terms of the circuit among the plurality of diodes 51 is connected to the pad 62P through a contact hole H provided in an interlayer insulating film above the anode wiring 61P.

Two conductor protrusions 64C are disposed to be included in the pad 62P in a plan view. The conductor protrusions 64C are connected to the collector layer 41C (FIG. 2) of the transistor 41 via the collector wirings 62C and 61C. Four conductor protrusions 64E are disposed to be included in each of the second-layer emitter wirings 62E. The conductor protrusions 64E are connected to the emitter layer 41E (FIG. 2) of the transistor 41 via the emitter wirings 62E and 61E.

Next, the excellent effects of the fifth embodiment will be described. Similar to the first embodiment, also in the fifth embodiment, a decrease in the output due to the clamping of the output voltage at high temperatures can be suppressed. Moreover, a sufficient effect of suppressing the damage of the transistor 41 can be maintained at low temperatures. In addition, since the pad 62P and the resistance element 52 are disposed to overlap each other in a plan view, it is not necessary to newly secure a region where the resistance element 52 is to be disposed.

### Sixth Embodiment

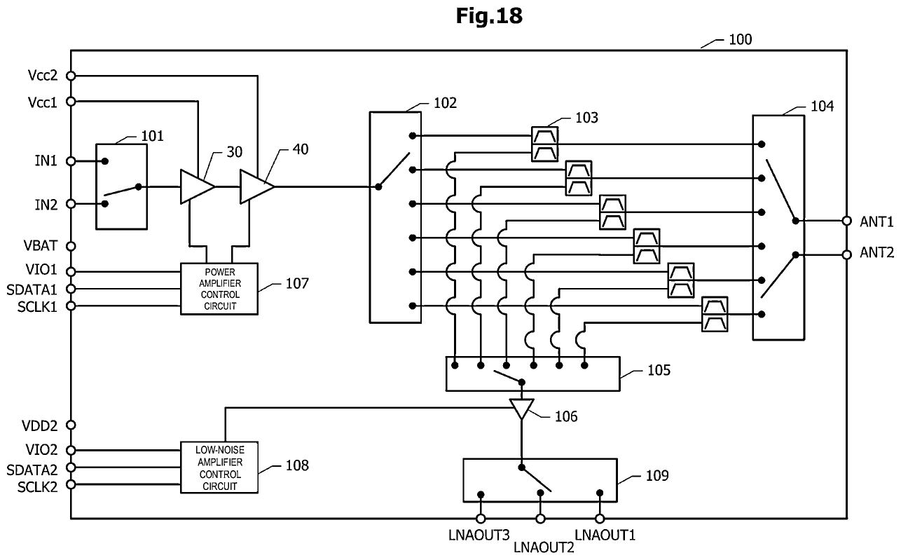

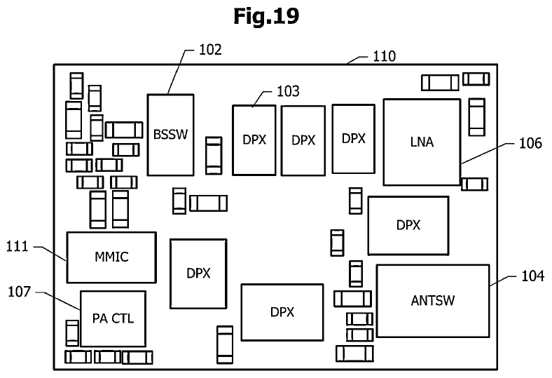

Next, a radio-frequency module according to a sixth embodiment will be described with reference to FIGS. 18 and 19. The radio-frequency module according to the sixth embodiment is mounted with the semiconductor device 20 according to any of the first to fifth embodiments.

FIG. 18 is a block diagram of a radio-frequency module 100 according to the sixth embodiment. The radio-frequency module 100 includes an input switch 101, the driver stage amplifier circuit 30, the power stage amplifier circuit 40, a band selection switch 102 for transmission, a plurality of duplexers 103, an antenna switch 104, a band selection switch 105 for reception, a low-noise amplifier 106, a power amplifier control circuit 107, a low-noise amplifier control circuit 108, and an output terminal selection switch 109 for reception. The radio-frequency module 100 has a function of performing transmission and reception in a frequency division duplex (FDD) system. In FIG. 18, the description of the impedance matching circuit to be inserted as necessary is omitted.

Two input-side contacts of the input switch 101 are connected to the respective radio-frequency signal input terminals IN1 and IN2. Radio-frequency signals are input from the two radio-frequency signal input terminals IN1 and IN2. In a case where the input switch 101 selects one contact from the two input-side contacts, a radio-frequency signal input to the selected contact is input to the driver stage amplifier circuit 30.

The radio-frequency signal amplified by the driver stage amplifier circuit 30 is input to the power stage amplifier circuit 40. The radio-frequency signal amplified by the power stage amplifier circuit 40 is input to an input-side contact of the band selection switch 102. In a case where the band selection switch 102 selects one contact from a plurality of output-side contacts, the radio-frequency signal amplified by the power stage amplifier circuit 40 is output from the selected contact.

The plurality of output-side contacts of the band selection switch 102 are connected to respective input nodes for transmission of the plurality of duplexers 103 prepared for each band. A radio-frequency signal is input to a duplexer 103 connected to an output-side contact selected by the band selection switch 102. The band selection switch 102 has a function of selecting one duplexer 103 from the plurality of duplexers 103 prepared for each band.

The antenna switch 104 has a plurality of circuit-side contacts and two antenna-side contacts. The plurality of circuit-side contacts of the antenna switch 104 are connected to respective input/output shared nodes of the plurality of duplexers 103. The two antenna-side contacts are connected to respective antenna terminals ANT1 and ANT2. Antennas are connected to the respective antenna terminals ANT1 and ANT2.

The antenna switch 104 connects the two antenna-side contacts to two respective contacts selected from the plurality of circuit-side contacts. In a case where the communication is performed using one band, the antenna switch 104 connects one circuit-side contact and one antenna-side contact. The radio-frequency signal amplified by the power stage amplifier circuit 40 and passed through a duplexer 103 for a corresponding band is transmitted from an antenna connected to a selected antenna-side contact.

The band selection switch 105 for reception has six input-side contacts. Each of the six input-side contacts of the band selection switch 105 is connected to an output node for reception of the duplexer 103. An output-side contact of the band selection switch 105 is connected to the low-noise amplifier 106. A reception signal that has passed through the duplexer 103 connected to an input-side contact selected by the band selection switch 105 is input to the low-noise amplifier 106.

A circuit-side contact of the output terminal selection switch 109 is connected to an output node of the low-noise amplifier 106. Three terminal-side contacts of the output terminal selection switch 109 are connected to respective reception signal output terminals LNAOUT1, LNAOUT2, and LNAOUT3. A reception signal amplified by the low-noise amplifier 106 is output from a reception signal output terminal selected by the output terminal selection switch 109.

Power supply voltages are applied from the power terminal Vcc1 and the power terminal Vcc2 to the driver stage amplifier circuit 30 and the power stage amplifier circuit 40, respectively. The power amplifier control circuit 107 is connected to a power terminal VIO1, a control signal terminal SDATA1, and a clock terminal SCLK1. The power amplifier control circuit 107 controls the driver stage amplifier circuit 30 and the power stage amplifier circuit 40 on the basis of a digital control signal given to the control signal terminal SDATA1. More specifically, a desired base bias is supplied from an analog circuit inside the power amplifier control circuit 107 to the driver stage amplifier circuit 30 and the power stage amplifier circuit 40 on the basis of the digital control signal given to the control signal terminal SDATA1.

The low-noise amplifier control circuit 108 is connected to a power terminal VIO2, a control signal terminal SDATA2, and a clock terminal SCLK2. The low-noise amplifier control circuit 108 controls the low-noise amplifier 106 on the basis of a digital control signal given to the control signal terminal SDATA2. More specifically, a desired base bias is supplied from an analog circuit inside the low-noise amplifier control circuit 108 to the low-noise amplifier 106 on the basis of the digital control signal given to the control signal terminal SDATA2.

The radio-frequency module 100 is further provided with a power terminal VBAT and a drain voltage terminal VDD2. Power is supplied from the power terminal VBAT to the driver stage amplifier circuit 30, a bias circuit of the power stage amplifier circuit 40, and the power amplifier control circuit 107. A power supply voltage is applied from the drain voltage terminal VDD2 to the low-noise amplifier control circuit 108 or the like.

FIG. 19 is a plan view showing an example of the disposition of various circuit components mounted on a module substrate 110. A monolithic microwave integrated circuit (MMIC) 111, the power amplifier control circuit 107, the band selection switch 102, the plurality of duplexers 103, the low-noise amplifier 106, the antenna switch 104, other passive elements, and the like are mounted on the module substrate 110. The MMIC 111 includes the driver stage amplifier circuit 30 (FIG. 18) and the power stage amplifier circuit 40 (FIG. 18). These circuit components are mounted on the module substrate 110 by solder ball mounting, copper (Cu) pillar bump (CPB) mounting, face-up mounting, or the like.

For example, multilayer substrates such as printed wiring substrates or ceramic substrates are used for the module substrate 110. Instead of single-sided mounting as shown in FIG. 19, high-density mounting such as double-sided mounting or IC mounting into a substrate may be adopted. By adopting such high-density mounting, the radio-frequency module 100 (FIG. 18) can be made smaller.

Next, the excellent effects of the sixth embodiment will be described. The radio-frequency module according to the sixth embodiment uses the semiconductor device 20 according to any of the first to fifth embodiments. For this reason, it is possible to suppress a decrease in the output due to the clamping of the output voltage at high temperatures, and it is possible to maintain a sufficient effect of suppressing the damage of a transistor at low temperatures.

### Seventh Embodiment

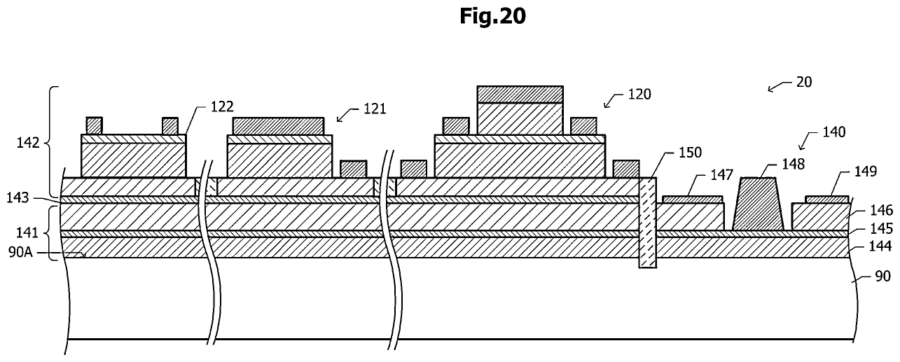

Next, a semiconductor device according to a seventh embodiment will be described with reference to FIG. 20. The description of the configurations in common with the semiconductor device 20 according to the first embodiment described with reference to FIGS. 1A to 7 will be omitted below.

FIG. 20 is a schematic sectional view of a part of the semiconductor device 20 according to the seventh embodiment. The semiconductor device 20 according to the seventh embodiment has a BiHEMT structure. That is, a heterojunction bipolar transistor (HBT) 120 and a high electron mobility transistor (HEMT) 140 are formed on the first surface 90A of the substrate 90. A HEMT structure layer 141 is formed on the first surface 90A of the substrate 90, and an HBT structure layer 142 is formed on the HEMT structure layer 141 via a separation layer 143. The separation layer 143 and the HBT structure layer 142 in a region where the HEMT 140 is formed are removed. An insulating portion 150 that penetrates the HEMT structure layer 141 in a thickness direction is disposed between a region where the HBT 120 is disposed and the region where the HEMT 140 is disposed.

The HEMT structure layer 141 includes an operation layer 144 including a carrier supply layer, a spacer layer, a channel layer, and the like, a Schottky layer 145 on the operation layer 144, and a contact layer 146 on the Schottky layer 145. A part of the contact layer 146 is removed, and the gate electrode 148 comes into a Schottky contact with the exposed Schottky layer 145. A source electrode 147 and a drain electrode 149 are disposed on the contact layer 146 so as to sandwich the gate electrode 148.

The HBT structure layer 142 includes each of the layers from the epitaxial layer 91 to the emitter layer 41E of the semiconductor device 20 (FIG. 2) according to the first embodiment. The HBT 120, the diode 121, and the resistance element 122 are configured by parts of these layers. For example, the HBT 120, the diode 121, and the resistance element 122 correspond to the transistor 41, the diode 51, and the resistance element 52 of the power stage amplifier circuit 40 of the semiconductor device 20 (FIG. 2) according to the first embodiment. Alternatively, the HBT 120, the diode 121, and the resistance element 122 correspond to the transistor 41, the diode 51, and the resistance element 52 of the power stage amplifier circuit 40 of the semiconductor device 20 (FIG. 16) according to the fifth embodiment.

Next, the excellent effects of the seventh embodiment will be described.

Similar to the first embodiment, also in the seventh embodiment, by inserting the resistance element 52 (FIG. 1B) configured with a part of the epitaxial layer into the output-side clamp circuit 50, it is possible to suppress a decrease in the output due to the clamping of the output voltage at high temperatures. Moreover, a sufficient effect of suppressing the damage of a transistor can be maintained at low temperatures. Moreover, by configuring the various switches, the low-noise amplifier 106, and the like shown in FIG. 18 by using the HEMT 140 formed on the substrate 90, it is possible to provide a single chip with more functions.

Each of the above-described embodiments is exemplary, and it goes without saying that partial replacement or combination of configurations shown in different embodiments is possible. The same operation and effect due to the same configuration of a plurality of embodiments will not be sequentially referred to for each embodiment. Moreover, the present disclosure is not limited to the above-described embodiments. For example, it will be obvious to a person skilled in the art that various changes, improvements, combinations, and the like are possible.

What is claimed is:

1. A semiconductor device comprising:
a substrate including a semiconductor;
a ground conductor on the substrate;
a transistor including a collector layer, a base layer, and an emitter layer that are laminated on the substrate; and
at least one clamp circuit that is configured with a plurality of elements on the substrate and that is connected between the collector layer and the ground conductor or between the base layer and the ground conductor,
wherein the plurality of elements of the clamp circuit include a diode circuit including a plurality of diodes, and a resistance element connected in series to the diode circuit, and
the resistance element is configured with a part of an epitaxial layer that is on the substrate.

2. The semiconductor device according to claim 1, wherein
the at least one clamp circuit includes a first clamp circuit, the first clamp circuit is connected between the collector layer of the transistor and the ground conductor, and the diode circuit included in the first clamp circuit includes a plurality of diodes connected in multiple stages in a forward direction from the collector layer toward the ground conductor.

3. The semiconductor device according to claim 2, wherein
each of the plurality of diodes included in the diode circuit is a pn junction diode, one semiconductor layer of the pn junction diode and the collector layer are configured with a part of the same epitaxial layer that is on the substrate, and another semiconductor layer of the pn junction diode and the base layer are configured with a part of the same epitaxial layer that is on the substrate.

4. The semiconductor device according to claim 2, wherein
a resistance value of the resistance element is from 1/10 to ½ of a load impedance of the transistor.

5. The semiconductor device according to claim 4, wherein
the load impedance is 50Ω, and the resistance value of the resistance element is from 5Ω to 25Ω.

6. The semiconductor device according to claim 1, wherein
the at least one clamp circuit includes a second clamp circuit, the second clamp circuit is connected between the base layer of the transistor and the ground conductor, and the diode circuit of the second clamp circuit includes at least two diodes connected in anti-parallel.

7. The semiconductor device according to claim 6, wherein
each of the plurality of diodes included in the diode circuit is a Schottky barrier diode, and a semiconductor layer of the Schottky barrier diode and the collector layer are configured with a part of the same epitaxial layer that is on the substrate.

8. The semiconductor device according to claim 6, wherein
a resistance value of the resistance element is 1/10 or more of an input impedance in a case where an amplifier circuit configured with the transistor is viewed from the second clamp circuit, and is equal to or less than an input impedance of the transistor.

9. The semiconductor device according to claim 8, wherein
the input impedance where the amplifier circuit configured with the transistor is viewed from the second clamp circuit is 50Ω, and the resistance value of the resistance element is from 5Ω to 50Ω.

10. The semiconductor device according to claim 1, wherein
each of the collector layer, the base layer, and the emitter layer of the transistor is configured with a part of a different epitaxial layer laminated on the substrate, and
the resistance element and the base layer are configured with different portions of the same epitaxial layer that is on the substrate.

11. The semiconductor device according to claim 1, further comprising:
a pad for external connection that is on the substrate and that is connected to the collector layer,
wherein in a plan view, the pad at least partially overlaps the resistance element and the plurality of diodes of the diode circuit.

12. The semiconductor device according to claim 3, wherein
a resistance value of the resistance element is from 1/10 to ½ of a load impedance of the transistor.

13. The semiconductor device according to claim 2, wherein
the at least one clamp circuit includes a second clamp circuit, the second clamp circuit is connected between the base layer of the transistor and the ground conductor, and the diode circuit of the second clamp circuit includes at least two diodes connected in anti-parallel.

14. The semiconductor device according to claim 3, wherein
the at least one clamp circuit includes a second clamp circuit, the second clamp circuit is connected between the base layer of the transistor and the ground conductor, and the diode circuit of the second clamp circuit includes at least two diodes connected in anti-parallel.

15. The semiconductor device according to claim 7, wherein
a resistance value of the resistance element is 1/10 or more of an input impedance in a case where an amplifier circuit configured with the transistor is viewed from the second clamp circuit, and is equal to or less than an input impedance of the transistor.

16. The semiconductor device according to claim 2, wherein
each of the collector layer, the base layer, and the emitter layer of the transistor is configured with a part of a different epitaxial layer laminated on the substrate, and
the resistance element and the base layer are configured with different portions of the same epitaxial layer that is on the substrate.

17. The semiconductor device according to claim 3, wherein
each of the collector layer, the base layer, and the emitter layer of the transistor is configured with a part of a different epitaxial layer laminated on the substrate, and
the resistance element and the base layer are configured with different portions of the same epitaxial layer that is on the substrate.

18. The semiconductor device according to claim 2, further comprising:
a pad for external connection that is on the substrate and that is connected to the collector layer,
wherein in a plan view, the pad at least partially overlaps the resistance element and the plurality of diodes of the diode circuit.

19. The semiconductor device according to claim 3, further comprising:
a pad for external connection that is on the substrate and that is connected to the collector layer,
wherein in a plan view, the pad at least partially overlaps the resistance element and the plurality of diodes of the diode circuit.

20. A semiconductor device comprising:
a substrate including a semiconductor;
a ground conductor on the substrate;
a driver stage amplifier circuit configured to amplify a radio-frequency signal input to a first input node to output the amplified radio-frequency signal from a first output node;
a power stage amplifier circuit that includes a second input node connected to the first output node and is configured to amplify a radio-frequency signal input to the second input node to output the amplified radio-frequency signal from a second output node;
an input-side clamp circuit connected between the first input node and the ground conductor;
an inter-stage clamp circuit connected between the second input node and the ground conductor; and
an output-side clamp circuit connected between the second output node and the ground conductor,
wherein the input-side clamp circuit includes a first diode circuit including at least two diodes connected in anti-parallel and a first resistance element connected in series to the first diode circuit,
the inter-stage clamp circuit includes a second diode circuit including at least two diodes connected in anti-parallel and a second resistance element connected in series to the second diode circuit,
the output-side clamp circuit includes a third diode circuit including a plurality of diodes connected in multiple stages in a forward direction from the second output node toward the ground conductor and a third resistance element connected in series to the third diode circuit,
each of the driver stage amplifier circuit and the power stage amplifier circuit includes a transistor including a collector layer, a base layer, and an emitter layer that are laminated on the substrate, and
each of the first resistance element, the second resistance element, and the third resistance element is configured with a part of an epitaxial layer that is on the substrate.
